(19) United States
(12) Patent Application Publication
(10) Pub. No.: US 2010/0102381 A1
(43) Pub. Date: Apr. 29, 2010

(54) POWER SEMICONDUCTOR DEVICE

(75) Inventors: Wataru SAITO, Kawasaki-Shi (JP); Syotaro ONO, Yokohama-Shi (JP); Hiroshi OHTA, Himeji-Shi (JP); Munehisa YABUZAKI, Yokohama-Shi (JP); Nana HATANO, Kawasaki-Shi (JP); Miho WATANABE, Tokyo (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/553,592

(22) Filed: Sep. 3, 2009

(30) Foreign Application Priority Data
Oct. 24, 2008 (JP) 2008-274022

(51) Int. Cl. H01L 29/78

(52) U.S. Cl. 257/329; 257/E29.257

(57) ABSTRACT

A power semiconductor device according to an embodiment of the present invention includes a first semiconductor layer of a first conductivity type, second semiconductor layers of the first conductivity type and third semiconductor layers of a second conductivity type, which are formed on the first semiconductor layer, have stripe shapes extending in a first horizontal direction, and are alternately arranged along a second horizontal direction orthogonal to the first horizontal direction, a fourth semiconductor layer of the second conductivity type, selectively formed on a surface of one of the third semiconductor layers, a fifth semiconductor layer of the first conductivity type, selectively formed on a surface of the fourth semiconductor layer, and formed into a stripe shape extending in the first horizontal direction without being formed into a stripe shape extending in the second horizontal direction, and a control electrode formed on the second, third, fourth, and fifth semiconductor layers via an insulating layer, and having a plane pattern periodical in the first horizontal direction and the second horizontal direction.

### CROSS REFERENCE TO RELATED APPLICATION

This application is based upon and claims the benefit of priority from the prior Japanese Patent Application No. 2008-274022, filed on Oct. 24, 2008, the entire contents of which are incorporated herein by reference.

### BACKGROUND OF THE INVENTION

1. Field of the Invention

The present invention relates to a power semiconductor device, for example, to a power semiconductor device in which a transistor is formed on a drift layer of a super junction structure.

2. Background Art

A widely known example of a power transistor for dealing with a large current is a vertical power MOSFET.

An on-state resistance of the vertical power MOSFET largely depends on an electric resistance of a drift layer (conductive layer). The electric resistance of the drift layer is varied according to a doping concentration in the drift layer. When the doping concentration in the drift layer is to be increased, it is necessary to consider a breakdown voltage of a pn junction formed by the drift layer and a base layer. This is because the doping concentration in the drift layer cannot be increased beyond a limit concentration determined according to the breakdown voltage.

In this way, there is a trade-off relationship between the breakdown voltage and the on-state resistance. It is important to improve the trade-off in order to achieve a low-power-consumption power device. The trade-off has a limit determined by a device material. Exceeding the limit is a key to achieve the power device having the on-state resistance lower than that of existing devices.

A known example for solving this problem is a super junction structure in which n pillar layers and p pillar layers are formed in a periodical manner in the drift layer. In the super junction structure, an impurity concentration in the n pillar layers and that in the p pillar layers can be set to a similar level, and a gap (pitch) between the pillar layers can be narrowed, to increase the impurity concentration in the pillar layers, thereby reducing the on-state resistance.

A MOSFET in which the super junction structure is formed in the drift layer has a switching characteristic faster than that of a conventional power MOSFET. One of the reasons for this is that the super junction structure is fully depleted at a low voltage to rapidly decrease a drain-source capacitance. A time derivative of a drain voltage (dV/dt) is in inverse proportion to a drain-source capacitance and a gate-drain capacitance which are output capacitances. Therefore, the time derivative dV/dt is increased with the decrease in the drain-source capacitance. It is desirable for lowering loss of the device that the switching time is shortened to reduce a switching loss. However, the large time derivative dV/dt also causes a switching noise (high-frequency noise). In order to reduce this noise, it is necessary to increase a gate resistance to decrease the time derivative dV/dt. However, this makes the switching time longer, and makes the switching loss larger. In this way, the trade-off relationship exists between the switching loss and the switching noise.

JP-A 2005-85990 (KOKAI) proposes a structure in which a super junction structure is formed into a stripe shape and a MOS gate electrode is formed into a mesh shape. As a result, both the switching loss and the switching noise can be reduced.

However, when the MOS gate electrode is formed into a mesh shape, an electric field is concentrated in a corner of a p base layer, and a parasitic bipolar is easily operated to lower an avalanche capability. On the other hand, if an area of an n⁺ source layer is reduced such that the parasitic bipolar is hardly operated, the on-state resistance is increased.

### SUMMARY OF THE INVENTION

An aspect of the present invention is, for example, a power semiconductor device including a first semiconductor layer of a first conductivity type, second semiconductor layers of the first conductivity type and third semiconductor layers of a second conductivity type, which are formed on the first semiconductor layer, have stripe shapes extending in a first horizontal direction, and are alternately arranged along a second horizontal direction orthogonal to the first horizontal direction, a fourth semiconductor layer of the second conductivity type, selectively formed on a surface of one of the third semiconductor layers, a fifth semiconductor layer of the first conductivity type, selectively formed on a surface of the fourth semiconductor layer, and formed into a stripe shape extending in the first horizontal direction without being formed into a stripe shape extending in the second horizontal direction, a control electrode formed on the second, third, fourth, and fifth semiconductor layers via an insulating layer, and having a plane pattern periodical in the first horizontal direction and the second horizontal direction, a first main electrode electrically connected to the fourth and fifth semiconductor layers, and a second main electrode electrically connected to the first semiconductor layer.

Another aspect of the present invention is, for example, a power semiconductor device including a first semiconductor layer of a first conductivity type, second semiconductor layers of the first conductivity type and third semiconductor layers of a second conductivity type, which are formed on the first semiconductor layer, have square plane shapes, and are alternately arranged along a first horizontal direction and a second horizontal direction orthogonal to the first horizontal direction, a fourth semiconductor layer of the second conductivity type, selectively formed on a surface of one of the third semiconductor layers, fifth semiconductor layers of the first conductivity type, each of which is selectively formed on a surface of the fourth semiconductor layer, and is formed into a stripe shape extending in the first or second horizontal direction, a control electrode formed on the second, third, fourth, and fifth semiconductor layers via an insulating layer, and having a plane pattern periodical in the first horizontal direction and the second horizontal direction, a first main electrode electrically connected to the fourth and fifth semiconductor layers, and a second main electrode electrically connected to the first semiconductor layer.

### BRIEF DESCRIPTION OF THE DRAWINGS

FIG. 1 shows a plan view and side sectional views schematically illustrating a configuration of a power semiconductor device according to a first embodiment;

FIG. 2 shows a plan view illustrating a plane pattern of a gate electrode of the first embodiment;

FIG. 3 shows capacitance versus drain voltage characteristics of the power semiconductor device of the first embodiment;

FIG. 4 shows a time dependence of a drain voltage in the power semiconductor device of the first embodiment;

FIG. 5 shows a plan view schematically illustrating a configuration of the power semiconductor device according to the first embodiment;

FIG. 6 shows a plan view schematically illustrating a configuration of the power semiconductor device according to the first embodiment;

FIG. 7 shows a plan view schematically illustrating a configuration of the power semiconductor device according to the first embodiment;

FIG. 8 shows a side sectional view schematically illustrating a configuration of the power semiconductor device according to the first embodiment;

FIG. 9 shows a plan view and a side sectional view schematically illustrating a configuration of the power semiconductor device according to the first embodiment;

FIG. 10 shows a plan view and a side sectional view schematically illustrating a configuration of a power semiconductor device according to a second embodiment;

FIG. 11 shows a plan view illustrating a plane pattern of a gate electrode of the second embodiment;

FIG. 12 shows a plan view schematically illustrating a configuration of the power semiconductor device according to the second embodiment;

FIG. 13 shows a plan view schematically illustrating a configuration of the power semiconductor device according to the second embodiment;

FIG. 14 shows a plan view schematically illustrating a configuration of a power semiconductor device according to a third embodiment;

FIG. 15 shows a plan view illustrating a plane pattern of a gate electrode of the third embodiment;

FIG. 16 shows a plan view schematically illustrating a configuration of a power semiconductor device according to a fourth embodiment;

FIG. 17 shows a plan view and side sectional views schematically illustrating a configuration of a power semiconductor device according to a fifth embodiment; and

FIG. 18 shows a plan view and side sectional views schematically illustrating another configuration of the power semiconductor device according to the fifth embodiment.

### DESCRIPTION OF THE EMBODIMENTS

Embodiments of the present invention will be described with reference to the drawings.

In the following embodiments, a first conductivity type is set to an n-type, while a second conductivity type is set to a p-type. Alternatively, the first conductivity type may be set to a p-type, while the second conductivity type is set to an n-type. In the drawings, the same component is designated by the same numeral.

### First Embodiment

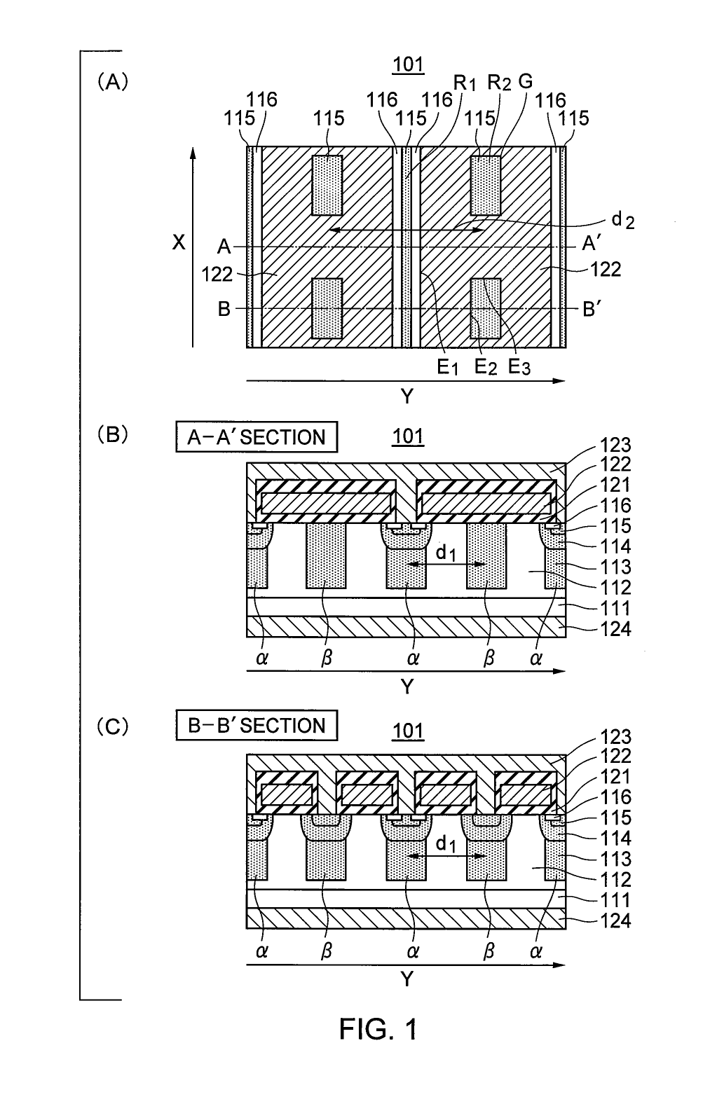

FIG. 1 shows a plan view and side sectional views schematically illustrating a configuration of a power semiconductor device according to a first embodiment. FIG. 1(A) is the plan view illustrating the power semiconductor device 101. FIG. 1(B) is the side sectional view taken along a line A-A′ in FIG. 1(A), and FIG. 1(C) is the side sectional view taken along a line B-B′ in FIG. 1(A). As illustrated in FIG. 1, the power semiconductor device 101 of the first embodiment includes a vertical power MOSFET.

The power semiconductor device 101 illustrated in FIG. 1 includes an n⁺ drain layer 111 that is an example of a first semiconductor layer, n pillar layers 112 that are an example of second semiconductor layers, p pillar layers 113 that are an example of third semiconductor layers, p base layers 114 that are an example of fourth semiconductor layers, p⁺ contact layers 115, n⁺ source layers 116 that are an example of fifth semiconductor layers, gate insulators 121 that are an example of insulating layers, gate electrodes 122 that are an example of control electrodes, a source electrode 123 that is an example of a first main electrode, and a drain electrode 124 that is an example of a second main electrode.

In the power semiconductor device 101 illustrated in FIG. 1, a super junction structure is formed by the n pillar layers 112 and the p pillar layers 113, and the n pillar layers 112 and the p pillar layers 113 are formed in a periodical manner on the n⁺ drain layer 111. The n pillar layers 112 and the p pillar layers 113 have stripe shapes extending in a first horizontal direction, and are alternately arranged along a second horizontal direction orthogonal to the first horizontal direction. In FIG. 1, the first horizontal direction is indicated by an arrow X, and the second horizontal direction is indicated by an arrow Y. Hereinafter, the first horizontal direction X is also referred to as stripe direction, and the second horizontal direction Y is also referred to as direction orthogonal to the stripe direction.

The p base layers 114 are selectively formed on surfaces of the p pillar layers 113, and the p⁺ contact layers 115 are selectively formed on surfaces of the p base layers 114. In the B-B′ section (FIG. 1(C)), the p base layers 114 and the p⁺ contact layers 115 are formed on every p pillar layer 113. On the other hand, in the A-A′ section (FIG. 1(B)), the p base layers 114 and the p⁺ contact layers 115 are formed on the p pillar layers 113 indicated by α, but are not formed on the p pillar layers 113 indicated by β.

The n⁺ source layers 116 are selectively formed on surfaces of the p base layers 114 and p⁺ contact layers 115. In both the A-A′ section and the B-B′ section, the n⁺ source layers 116 are formed on the p pillar layers 113 indicated by α, but are not formed on the p pillars layer 113 indicated by β.

The gate electrodes 122 are formed on the n pillar layers 112, p pillar layers 113, p base layers 114, p⁺ contact layers 115, and n⁺ source layers 116 via the gate insulators 121. The source electrode 123 is in contact with surfaces of the p⁺ contact layers 115 and n⁺ source layers 116 to be electrically connected to the p⁺ contacts layer 115 and n⁺ source layers 116. The source electrode 123 is also electrically connected to the p base layers 114 through the p⁺ contact layers 115. The drain electrode 124 is in contact with surfaces of the n⁺ drain layer 111 to be electrically connected to the n⁺ drain layer 111.

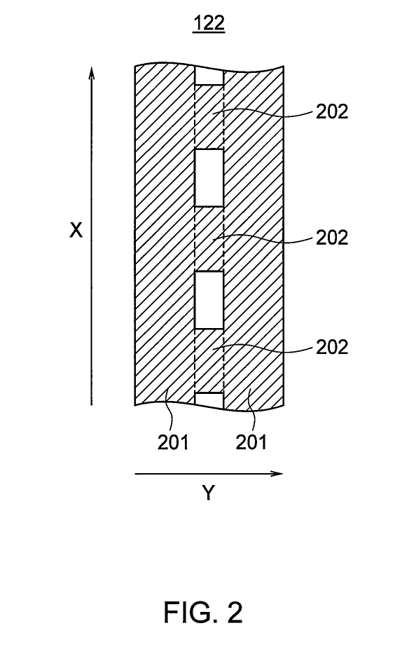

As illustrated in FIG. 1(A), each of the gate electrodes 122 of the first embodiment has a ladder-like plane pattern. The ladder-like plane pattern will be described in detail with reference to FIG. 2.

As illustrated in FIG. 2, each of the gate electrodes 122 includes two stripe portions 201 and plural connection portions 202. The stripe portions 201 have stripe shapes extending in the first horizontal direction. The connection portions 202 connect the two stripe portions 201 to each other. In the first embodiment, the ladder-like plane pattern is formed by the stripe portions 201 and the connection portions 202 as illustrated in FIG. 2. The plane pattern is formed in a periodical manner in the second horizontal direction by the stripe portions 201, and is also formed in a periodical manner in the first horizontal direction by the connection portions 202.

Referring back to FIG. 1, the description will be continued. However, the description regarding the stripe portions 201 and connection portions 202 will be described with reference to FIG. 2 as appropriate.

As can be seen from FIGS. 1(A) and 2, the A-A′ section of FIG. 1(B) corresponds to a section traversing both the stripe portions 201 and the connection portions 202. On the other hand, the B-B′ section of FIG. 1(C) corresponds to a section traversing only the stripe portions 201. As can be seen from FIGS. 1(B) and 1(C), the stripe portions 201 are mainly formed on the n pillar layers 112, the p base layers 114, the p⁺ contact layers 115, and the n⁺ source layers 116, and the connection portions 202 are mainly formed on the p pillar layers 113. In this embodiment, each stripe portion 201 is formed on an n pillar layer 112, p base layers 114, p⁺ contact layers 115, and an n⁺ source layer 116, and each connection portion 202 is formed on a p pillar layer 113.

The p base layers 114 and the p⁺ contact layers 115 are formed by using the gate electrodes 122 as a mask. Therefore, the p base layers 114 and the p⁺ contact layers 115 are selectively formed in opening regions of the ladder-like gate electrodes 122.

In FIGS. 1(B) and 1(C), a repetition interval of the super junction structure in the second horizontal direction is indicated by d₁. As illustrated in FIGS. 1(B) and 1(C), the repetition interval d₁ corresponds to a repetition interval of the p pillar layers 113 in the second horizontal direction. On the other hand, in FIG. 1(A), a repetition interval of the ladder-like plane patterns in the second horizontal direction is indicated by d₂. In the first embodiment, the repetition interval d₂ is twice as large as the repetition interval d₁. Therefore, in FIGS. 1(B) and 1(C), a ratio of the number of p pillar layers 113 indicated by α and the number of p pillar layers 113 indicated by β is 1:1. The repetition interval d₂ may be n (n is an integer more than two) times as large as the repetition interval d₁. In such cases, the ratio of the number of p pillar layers 113 indicated by α and the number of p pillar layers 113 indicated by β is 1:(n−1).

As described above, the p base layers 114 and the p⁺ contact layers 115 are formed by using the gate electrodes 122 as the mask. Therefore, the p base layers 114 and the p⁺ contact layers 115 are formed in regions R₁ and R₂ of FIG. 1(A). Each of the regions R₁ is sandwiched between the ladders of the gate electrodes 122. Each of the regions R₂ corresponds to a ladder stage of a gate electrode 122, and is surrounded by the individual gate electrode 122. The p base layers 114 and the p⁺ contact layers 115 are formed into stripe shapes in the regions R₁ and into island shapes in the regions R₂.

Three types of edges E₁, E₂, and E₃ of the gate electrodes 122 are also illustrated in FIG. 1(A). Each of the edges E₁ is an edge of a stripe portion 201, facing a region R₁. Each of the edges E₂ is an edge of a stripe portion 201, facing a region R₂. Each of the edges E₃ is an edge of a connection portion 202, facing a region R₂. Each of the edges E₁ is an example of a first edge of the invention, and each of the edges E₂ and E₃ is an example of a second edge of the invention.

In the first embodiment, the n⁺ source layers 116 can be formed under the edges E₁, E₂, and E₃. When the n⁺ source layers 116 are formed under the edges E₁ or E₂, the n⁺ source layers 116 are formed into stripe shapes extending in the first horizontal direction. On the other hand, when the n⁺ source layers 116 are formed under the edges E₃, the n⁺ source layers 116 are formed into stripe shapes extending in the second horizontal direction.

However, in the first embodiment, the n⁺ source layers 116 are formed only under the edges E₁, but are not formed under the edges E₂ and E₃. Therefore, the stripe-shaped n⁺ source layers 116 extending in the first horizontal direction are formed, while the stripe-shaped n⁺ source layers 116 extending in the second horizontal direction are not formed. In this way, in the first embodiment, the n⁺ source layers 116 are formed under the stripe portions 201 (partially), but are not formed under the connection portions 202.

As described above, the gate electrodes 122 are formed on the n pillar layers 112, p pillar layers 113, p base layers 114, and n⁺ source layers 116 in the first embodiment. Further, the n⁺ source layers 116 are formed into stripe shapes extending in the first horizontal direction without being formed into stripe shapes extending in the second horizontal direction. According to the configuration of the first embodiment, the loss and noise in switching can be reduced while a low on-state resistance and a high avalanche capability are maintained. The reason for this will be described in detail below.

First, the reason why the loss and noise in switching can be reduced will be described.

When a drain voltage V becomes high, the super junction structure is fully depleted to decrease a drain-source capacitance Cds. The regions under the gate electrodes 122 sandwiched between the p base layers 114 are also depleted to decrease a gate-drain capacitance Cgd. When the drain-source capacitance Cds and the gate-drain capacitance Cgd are decreased, a time derivative of the drain voltage (dV/dt) is increased to generate noise. If, conversely, the gate-drain capacitance Cgd is increased with increasing drain voltage V, the time derivative dV/dt will be decreased and noise can be reduced.

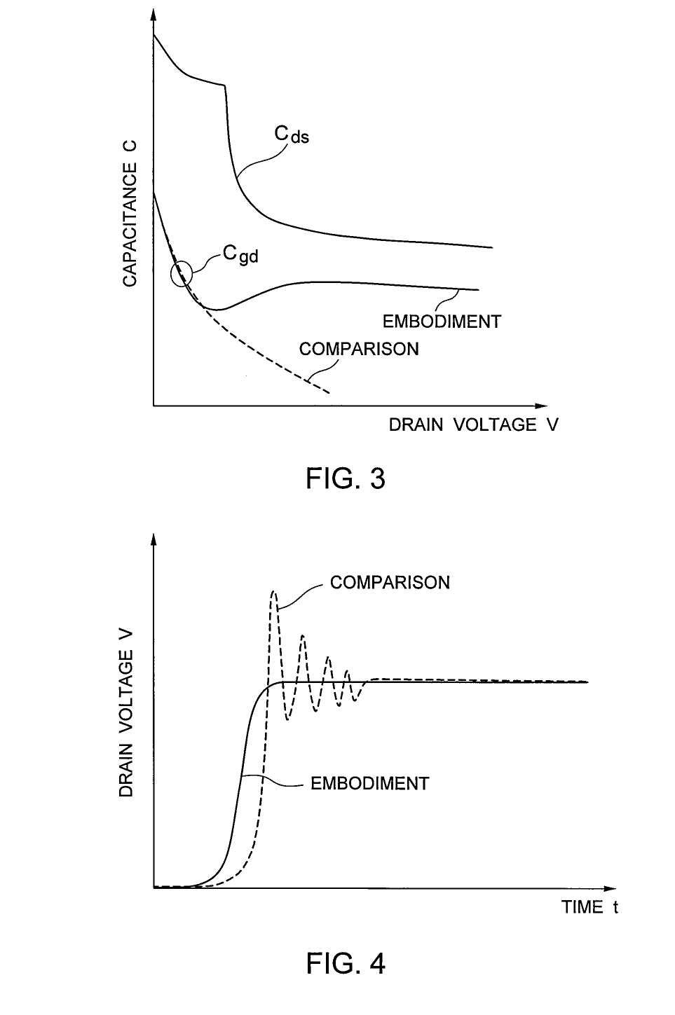

Therefore, in the first embodiment, the gate electrodes 122 are formed on the p pillar layers 113. Because the p pillar layers 113 are connected to the source electrode 123 through the p base layers 114, a capacitance between the p pillar layers 113 and the gate electrodes 122 is a gate-source capacitance Cgs. However, when the gate electrodes 122 are formed on the p pillar layers 113, the p pillar layers 113 are depleted by high voltage application, and an electric flux line is connected between the drain electrode 124 and the gate electrodes 122 through the p pillar layers 113, that is, the gate-drain capacitance Cgd is generated. Therefore, as illustrated in FIG. 3, a characteristic in which the gate-drain capacitance Cgd is increased during high voltage application can be realized. In FIG. 3, the gate-drain capacitance Cgd shown by a solid line represents the gate-drain capacitance Cgd of the first embodiment, that is, the gate-drain capacitance Cgd in a case where the gate electrodes 122 are formed on the p pillar layers 113. On the other hand, the gate-drain capacitance Cgd shown by a broken line represents a gate-drain capacitance Cgd of a comparative example, that is, the gate-drain capacitance Cgd in a case where the gate electrodes 122 are not formed on the p pillar layers 113.

Accordingly, in the first embodiment, the time derivative dV/dt during high voltage application can be suppressed to a small level. Therefore, in the first embodiment, an external gate resistance is decreased to perform high-speed switching, so that a ringing noise can be reduced as illustrated in FIG. 4 even if the loss in switching is decreased. In FIG. 4, a solid line represents the drain voltage V of the first embodiment, that is, the drain voltage V in a case where the gate electrodes 122 are formed on the p pillar layers 113. On the other hand, a broken line represents the drain voltage V of the comparative example, that is, the drain voltage V in a case where the gate electrodes 122 are not formed on the p pillar layers 113.

The characteristics shown in FIGS. 3 and 4 can be realized by forming the gate electrodes 122 on the p pillar layers 113. Further, in the first embodiment, by forming the n⁺ source layers 116 into stripe shapes extending in the first horizontal direction without forming into stripe shapes extending in the second horizontal direction, the low on-state resistance and the high avalanche capability can be realized. Next, the reason for this will be described below.

In FIG. 1(A), corners of the gate electrodes 122 are indicated by G. As described above, the p base layers 114 are formed by using the gate electrodes 122 as a mask. Therefore, corners of the p base layers 114 are formed almost under the corners of the gate electrodes 122. Therefore, in general, the number of corners of the p base layers 114 is increased as the number of corners of the gate electrodes 122 is increased.

In this embodiment, the gate electrodes 122 have the ladder-like plane patterns. The ladder-like gate electrodes 122 have an advantage that the number of corners is smaller than that of mesh gate electrodes. Therefore, the number of corners of the p base layers 114 can be decreased by employing the ladder-like gate electrodes 122 instead of the mesh gate electrodes.

Furthermore, the n⁺ source layers 116 are formed only under the edges E₁ in the first embodiment. Therefore, the n⁺ source layers 116 are not formed on surfaces of the corners of the p base layers 114. Accordingly, parasitic bipolar transistors are not formed at the corners of the p base layers 114 at which the avalanche breakdown is easily generated by the electric field concentration. Therefore, the high avalanche capability can be realized in the first embodiment.

Furthermore, the stripe-shaped n⁺ source layers 116 are formed on surfaces of the stripe-shaped p base layers 114 sandwiched between the ladders, in this embodiment. When the voltage is applied to the gate electrodes 122, the n⁺ source layers 116 and the n pillar layers 112 are electrically connected through inverting channels, and the MOSFETs are turned on.

At this time, if the gate electrodes 122 have stripe shapes, each n pillar layer 112 is electrically connected to n⁺ source layers 116 located on its both sides. On the other hand, in the first embodiment, because only one n⁺ source layer 116 is formed on one side of each n pillar layer 112, each n pillar layer 112 is electrically connected to one n⁺ source layer 116 existing only on its one side. Therefore, in the first embodiment, the channel resistance is increased compared with the case where the gate electrodes 122 have stripe shapes. However, because the channel resistance is extremely smaller than the resistance of the n pillar layers 112, the on-state resistance in the first embodiment becomes substantially equal to that in the case where the gate electrodes 122 have stripe shapes. Accordingly, the low on-state resistance can be maintained in the first embodiment.

For the reasons above, the loss and noise in switching can be reduced while the low on-state resistance and the high avalanche capability are maintained.

In the first embodiment, the gate electrodes 122 have the ladder-like plane patterns. Alternatively, the gate electrodes 122 may have other plane patterns that are formed in a periodical manner in both the first horizontal direction and the second horizontal direction. However, the ladder-like plane patterns have an advantage that the number of corners of the p base layers 114 is decreased. When the number of corners of the p base layers 114 are decreased, the area of the p pillar layers 113 in which the n⁺ source layers 116 are not provided is reduced, so that the increase in on-state resistance can be suppressed to a small level. The ladder-like plane patterns also have an advantage that the structure in which the gate electrodes 122 are located on the p pillar layers 113 can be realized.

In the first embodiment, the repetition interval d₂ of the ladder-like plane patterns is twice as large as the repetition interval d₁ of the super junction structure. Alternatively, the repetition interval d₂ of the ladder-like plane patterns may be n (n is an integer more than two) times as large as the repetition interval d₁ of the super junction structure. In the case where d₂=2×d₁, advantageously the number of p pillar layers 113 with which the n⁺ source layers 116 are not provided can be minimized to suppress the increase in on-state resistance to the minimum.

Desirable settings of various parameters regarding the power semiconductor device 101 will be described below.

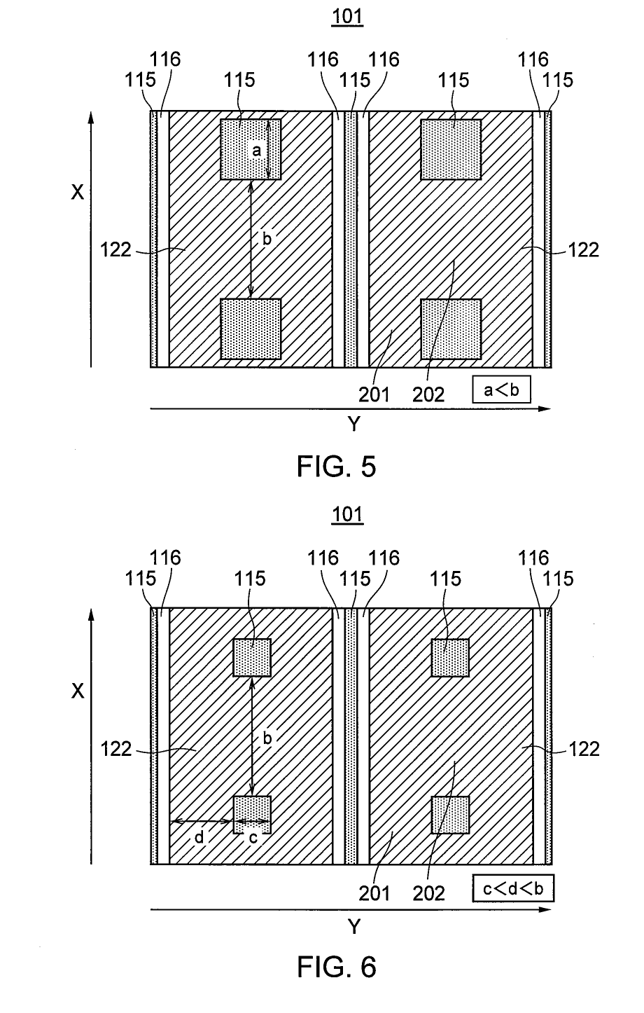

FIG. 5 shows a plan view schematically illustrating a configuration of the power semiconductor device 101 of the first embodiment. In FIG. 5, the letter “a” designates a distance between the connection portions 202 adjacent to each other in the first horizontal direction (stripe direction), and the letter “b” designates a width of each of the connection portions 202 in the first horizontal direction.

In order to increase the gate-drain capacitance during high voltage application, it is effective to increase the area of the gate electrodes 122 formed on the p pillar layers 113. That is, it is effective to enlarge the area of the connection portions 202 as much as possible. As illustrated in FIG. 5, desirably the width “b” of each of the connection portions 202 in the first horizontal direction is larger than the distance “a” between the connection portions 202 adjacent to each other in the first horizontal direction. This allows the area of the connection portions 202 to be enlarged.

FIG. 6 shows a plan view schematically illustrating a configuration of the power semiconductor device 101 of the first embodiment. In FIG. 6, the letter “b” designates the width of each of the connection portions 202 in the first horizontal direction, as in FIG. 5. Further, the letter “c” designates a distance between the sprite portions 201 adjacent to each other in the second horizontal direction (direction orthogonal to the stripe direction), i.e., a width of each of the connection portions 202 in the second horizontal direction, and the letter “d” designates a width of each of the stripe portions 201 in the second horizontal direction.

The voltage change (dV/dt) in switching is easier to control using the external gate resistance, when the gate-drain capacitance Cgd is increased and the drain-source capacitance Cds is decreased. Therefore, in order to enlarge the area of the gate electrodes 122 to increase the gate-drain capacitance Cgd, desirably the width “d” of each of the stripe portions 201 in the second horizontal direction is larger than the distance “c” between the sprite portions 201 adjacent to each other in the second horizontal direction, as illustrated in FIG. 6. This enables the area of the gate electrode 122 to be enlarged.

In order to reduce the loss and noise in switching, it is necessary to enlarge the area of the gate electrodes 122 on the p pillar layers 113. Therefore, desirably the width “b” of each of the connection portions 202 in the first horizontal direction is larger than the width “d” of each of the stripe portions 201 in the second horizontal direction.

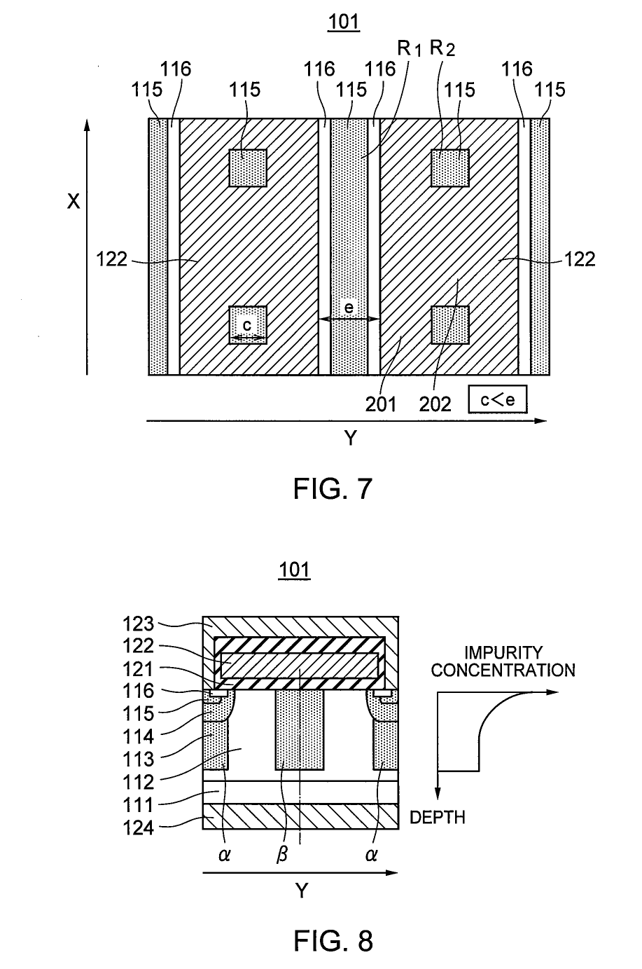

FIG. 7 shows a plan view schematically illustrating a configuration of the power semiconductor device 101 of the first embodiment. In FIG. 7, the letter “c” designates the distance between the sprite portions 201 adjacent to each other in the second horizontal direction, i.e., the width of each of the connection portions 202 in the second horizontal direction, as in FIG. 6. Further, the letter “e” designates a distance between the ladder-like gate electrodes 122 adjacent to each other in the second horizontal direction.

In the regions R₁ sandwiched between the ladder-like gate electrodes 122, parasitic bipolar transistors are formed because the n⁺ source layers 116 are formed. In order to realize the high avalanche capability, it is effective to lower a hole escape resistance in the regions R₁. On the other hand, in the regions R₂ corresponding to the ladder stages of the ladder-like gate electrodes 122, parasitic bipolar transistors are not formed because the n⁺ source layers 116 are not formed. Therefore, desirably the distance “e” between the ladder-like gate electrodes 122 adjacent to each other in the second horizontal direction is longer than the distance “c” between the sprite portions 201 adjacent to each other in the second horizontal direction, as illustrated in FIG. 7.

FIG. 8 shows a side sectional view schematically illustrating a configuration of the power semiconductor device 101 of the first embodiment. FIG. 8 is the side sectional view taken along the line A-A′ in FIG. 1. FIG. 8 also illustrates an impurity concentration profile in each of the p pillar layers 113 indicated by β. In the impurity concentration profile of FIG. 8, a vertical axis indicates a depth (μm) and a horizontal axis indicates an impurity concentration (cm⁻³).

In the first embodiment, the gate-drain capacitance Cgd is increased when the p pillar layers 113 are depleted. Further, when the impurity concentration is increased in the surfaces of the p pillar layers 113 under the gate electrodes 122, the drain voltage V at which the gate-drain capacitance Cgd starts to increase can be high. Therefore, as illustrated in FIG. 8, desirably the impurity concentration in the p pillar layers 113 under the gate electrodes 122 is increased as the distance to the gate electrodes 133 is shorter. Such an impurity concentration profile can be formed by crosswise diffusion of the p base layers 114.

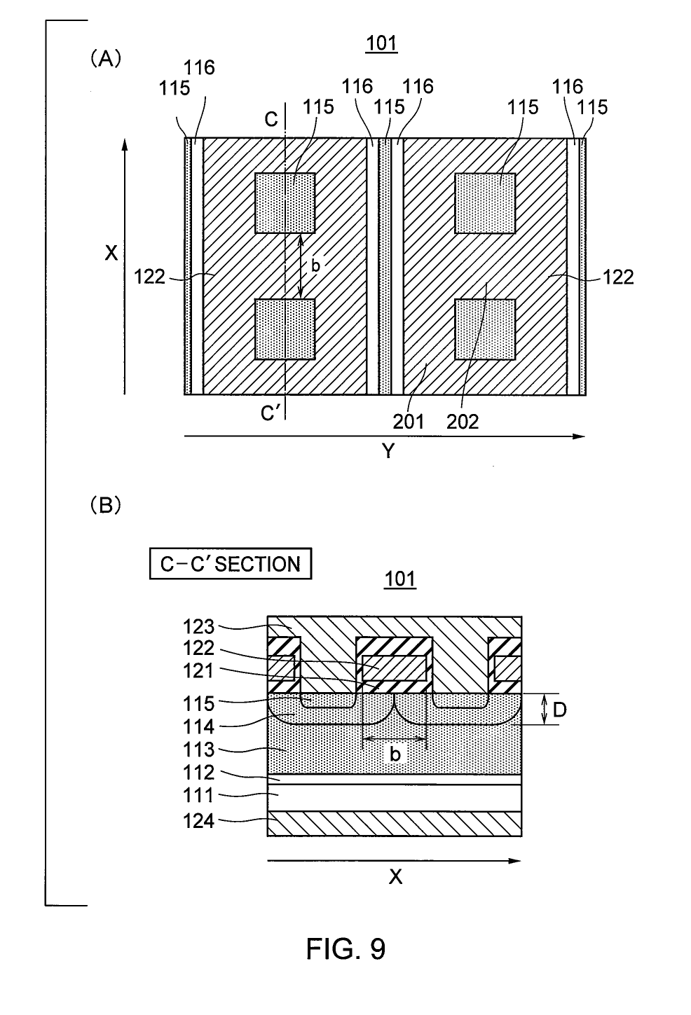

FIG. 9 shows a plan view and a side sectional view schematically illustrating a configuration of the power semiconductor device according to the first embodiment. FIG. 9(A) is the plan view illustrating the power semiconductor device 101. FIG. 9(B) is the side sectional view taken along a line C-C′ in FIG. 9(A). The C-C′ section of FIG. 9(B) corresponds to a section traversing the connection portions 202 in the first horizontal direction. In FIGS. 9(A) and 9(B), the letter “b” designates the width of each of the connection portions 202 in the first horizontal direction. In FIG. 9(B), the letter “D” designates a diffusion depth of each of the p base layers 114.

In the first embodiment, the impurity concentration in the surfaces of the p pillar layers 113 can be controlled by adjusting the width “b”. In a case where the longitudinal diffusion is substantially equal to the crosswise diffusion in the p base layers 114, when the width “b” is substantially twice as large as the diffusion depth “D”, ends of the adjacent p base layers 114 overlap each other as illustrated in FIG. 9(B).

On the other hand, when the width “b” is equal to or lower than the diffusion depth “D”, the p base layers 114 are connected to each other and the surface concentration is excessively increased. In such a case, the depletion does not occur during high voltage application, and the gate-drain capacitance Cgd is not increased. When the width “b” is at least four times as large as the diffusion depth “D”, a ratio of volumes of the p base layers 114 to volumes of the regions under the gate electrodes 122 becomes a half or less, eliminating the effect that the drain voltage V at which the gate-drain capacitance Cgd starts to increase is increased. Therefore, desirably the width “b” is one to four times as large as the diffusion depth “D”.

As described above, in the first embodiment, the gate electrodes 122 are formed on the n pillar layers 112, p pillar layers 113, p base layers 114, and n⁺ source layers 116, so that both the high-speed switching and the low noise level can be achieved. Further, because the gate electrodes 122 are formed on the p pillar layers 113, the gate-drain capacitance is increased during high voltage application.

Further, in the first embodiment, the n⁺ source layers 116 are formed into stripe shapes extending in the first horizontal direction without being formed into stripe shapes extending in the second horizontal direction, so that the low on-state resistance and the high avalanche capability can be maintained. In this embodiment, the n⁺ source layers 116 are not formed in the portions that do not constitute the current paths.

Further, in the first embodiment, the gate electrodes 122 have the plane patterns periodical in the first horizontal direction and the second horizontal direction. Thereby, the structure in which the gate electrodes 122 are located on the p pillar layers 113 is realized. In this embodiment, this structure is realized by the ladder-like plane patterns.

Hereinafter, power semiconductor devices 101 according to second to fifth embodiments will be described. The power semiconductor devices 101 of the second to fifth embodiments are modifications of the power semiconductor device 101 of the first embodiment. In the second to fifth embodiments, differences from the first embodiment will mainly be described.

### Second Embodiment

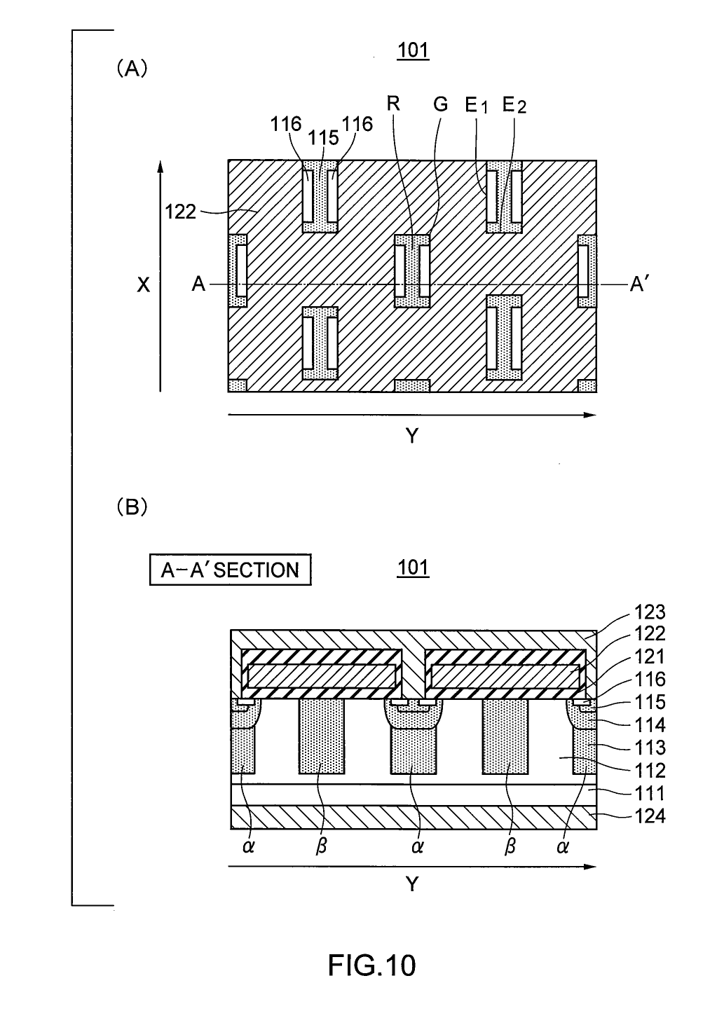

FIG. 10 shows a plan view and a side sectional view schematically illustrating a configuration of a power semiconductor device according to a second embodiment. FIG. 10(A) is the plan view illustrating the power semiconductor device 101. FIG. 10(B) is the side sectional view taken along a line A-A′ in FIG. 10(A). As illustrated in FIG. 10, the power semiconductor device 101 of the second embodiment includes a vertical power MOSFET.

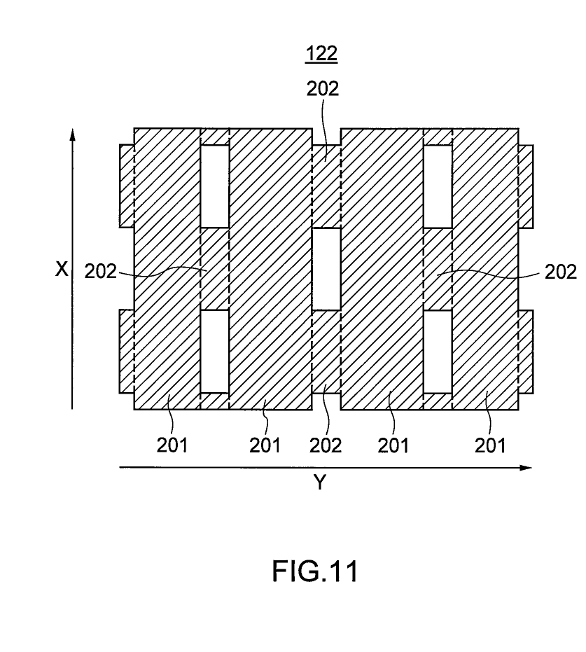

As illustrated in FIG. 1(A), the gate electrodes 122 of the first embodiment have the ladder-like plane patterns. On the other hand, as illustrated in FIG. 10(A), a gate electrode 122 of the second embodiment has an offset mesh plane pattern. Details of the offset mesh plane pattern will be described with reference to FIG. 11.

As illustrated in FIG. 11, the gate electrode 122 of the second embodiment includes plural stripe portions 201 and plural connection portions 202. The stripe portions 201 have stripe shapes extending in the first horizontal direction. The connection portions 202 connect the stripe portions 201 adjacent to each other. In the second embodiment, the offset mesh plane pattern is formed by the stripe portions 201 and connection portions 202 as illustrated in FIG. 11. The offset mesh plane pattern is formed in a periodical manner in the second horizontal direction by the stripe portions 201, and is also formed in a periodical manner in the first horizontal direction by the connection portions 202.

Referring back to FIG. 10, the description will be continued. However, the description regarding the stripe portions 201 and connection portions 202 will be described with reference to FIG. 11 as appropriate.

As can be seen from FIGS. 10(A) and 11, the A-A′ section of FIG. 10(B) corresponds to a section traversing both the stripe portions 201 and the connection portions 202. As can be seen from FIGS. 10 and 11, the stripe portions 201 are mainly formed on the n pillar layers 112, the p base layers 114, the p⁺ contact layers 115, and the n⁺ source layers 116, and the connection portions 202 are mainly formed on the p pillar layers 113.

As described above, because the p base layers 114 and the p⁺ contact layers 115 are formed by using the gate electrode 122 as a mask, the p base layers 114 and the p⁺ contact layers 115 are selectively formed in opening regions of the offset mesh gate electrode 122.

As described above, in the second embodiment, the gate electrode 122 is formed on the n pillar layers 112, p pillar layers 113, p base layers 114, and n⁺ source layers 116. As a result, the gate-drain capacitance is increased when the super junction structure is fully depleted, thereby realizing the high-speed switching and the low noise level.

As described above, the p base layers 114 and the p⁺ contact layers 115 are formed by using the gate electrode 122 as a mask. Therefore, the p base layers 114 and the p⁺ contact layers 115 are formed in regions R of FIG. 10(A). The regions R correspond to mesh holes of the gate electrode 122, and are surrounded by the gate electrode 122. The p base layers 114 and the p⁺ contact layers 115 are formed into island shapes in the regions R, respectively.

Two types of edges E₁ and E₂ of the gate electrode 122 are also illustrated in FIG. 10(A). Each of the edges E₁ is an edge of the stripe portions 201, facing a region R. Each of the edges E₂ is an edge of the connection portions 202, facing a region R.

In the second embodiment, the n⁺ source layers 116 can be formed under the edges E₁ and E₂. When the n⁺ source layers 116 are formed under the edges E₁, the n⁺ source layers 116 are formed into stripe shapes extending in the first horizontal direction. On the other hand, when the n⁺ source layers 116 are formed under the edges E₂, the n⁺ source layers 116 are formed into stripe shapes extending in the second horizontal direction.

However, in the second embodiment, the n⁺ source layers 116 are formed only under the edges E₁, but are not formed under the edges E₂. Therefore, the stripe-shaped n⁺ source layers 116 extending in the first horizontal direction is formed, while the stripe-shaped n⁺ source layers 116 extending in the second horizontal direction are not formed. In this way, in the second embodiment, the n⁺ source layers 116 are formed under the stripe portions 201 without being formed under the connection portions 202.

In FIG. 10(A), corners of the gate electrode 122 are indicated by G. As described above, because the p base layers 114 are formed by using the gate electrode 122 as a mask, corners of the p base layers 114 are formed almost under the corners of the gate electrode 122. Each of the corners G corresponds to an intersection of an edge E₁ and an edge E₂.

In this embodiment, the n⁺ source layers 116 are formed in portions except for the underneath of the corners G, in portions under the edges E₁. Therefore, the n⁺ source layers 116 are not formed on surfaces of the corners G of the p base layers 114. Accordingly, in this embodiment, parasitic bipolar transistors are not formed at the corners of the p base layers 114 at which the avalanche breakdown is easily generated by the electric field concentration. Thereby, the low on-state resistance and the high avalanche capability can be realized in the second embodiment.

Desirable settings of various parameters regarding the power semiconductor device 101 of the second embodiment will be described below.

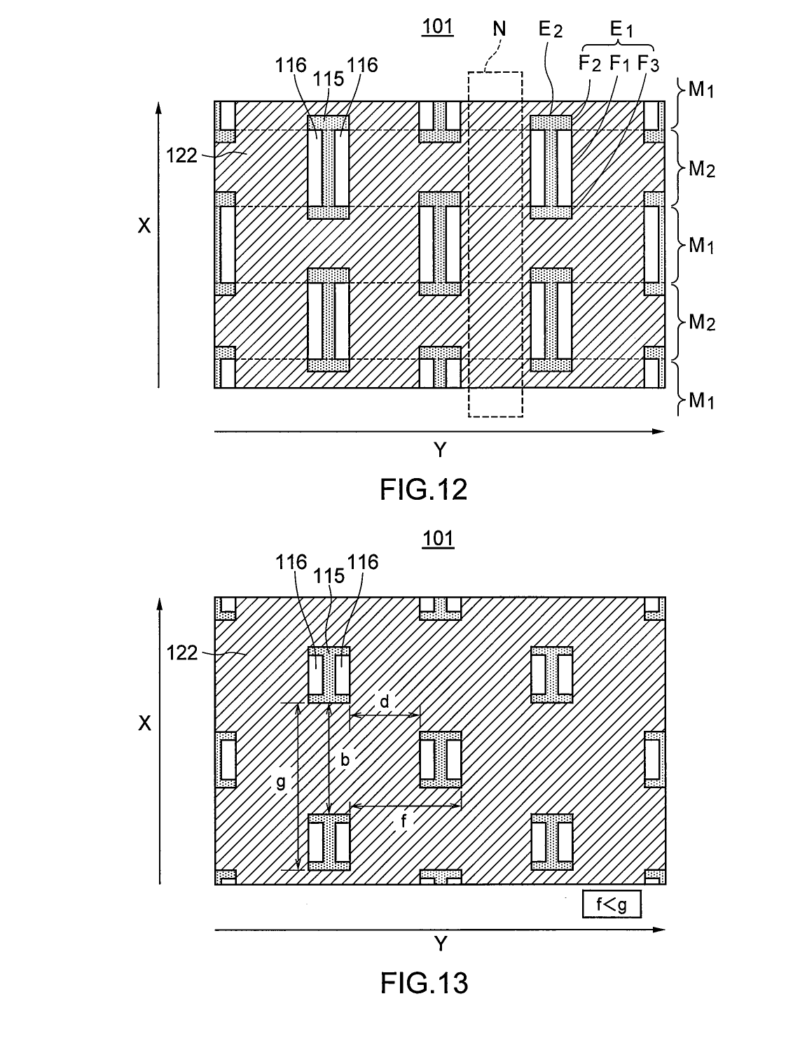

FIG. 12 shows a plan view schematically illustrating a configuration of the power semiconductor device 101 of FIG. 10.

In FIG. 12, a region in which an n pillar layer 112 exists is indicated by a broken line N. Further, alternately-repeated regions M₁ and M₂, which are partitioned by straight lines extending in the second horizontal direction, are also illustrated in FIG. 12. The regions M₁ and M₂ are alternately provided along the first horizontal direction. The regions M₁ and M₂ are respectively examples of first and second regions of the invention.

In the regions M₁, the n pillar layer 112 indicated by the broken line N is electrically connected to an n⁺ source layer 116 located on the left of the n pillar layer 112. In the regions M₂, the n pillar layer 112 indicated by the broken line N is electrically connected to an n⁺ source layer 116 located on the right of the n pillar layer 112. In this way, the n pillar layer 112 is electrically connected anywhere to an n⁺ source layer 116 located on the right or left of the n pillar layer 112. The same holds true for other n pillar layers 112 of the power semiconductor device 101. In the second embodiment, the low on-state resistance is realized by the above-described configuration. The side surfaces on the right and left of each n pillar layer 112 are examples of first and second side surfaces of the invention. These side surfaces face the adjacent p pillar layers 113. Each n pillar layer 112 may include portions electrically connected to the n⁺ source layers 116 on both sides of the n pillar layer 112.

Referring to FIG. 12, in an edge E₁, F₁ designates a portion facing an n⁺ source layer 116, and F₂ and F₃ designate portions that do not face the n⁺ source layer 116. In the second embodiment, in each edge, desirably the total length of the portion(s) facing the n⁺ source layer 116 is longer than the total length of the portion(s) that does not face the n⁺ source layer 116. That is, desirably the length of the portion F₁ is longer than the total of the lengths of the portions F₂ and F₃. As a result, the structure in which each n pillar layer 112 is electrically connected anywhere to the n⁺ source layer 116 located on the right or left of the n pillar layer 112 is easier to realize. The portion F₁ is an example of a first portion of the invention, and the portions F₂ and F₃ are an example of a second portion of the invention.

FIG. 13 shows a plan view schematically illustrating a configuration of the power semiconductor device 101 of FIG. 10.

In FIG. 13, the letter “f” designates a repetition interval of the plane pattern of the gate electrode 122 in the second horizontal direction, and the letter “g” designates a repetition interval of the plane pattern of the gate electrode 122 in the first horizontal direction.

In order to reduce the loss and noise in switching, it is necessary to enlarge the area of the gate electrode 122 on the p pillar layers 113. Therefore, as described above with reference to FIG. 6, desirably the first horizontal width of each of the connection portions 202 is larger than the second horizontal width of each of the stripe portions 201 (b>d). However, in general, while the repetition interval “g” of the gate electrode 122 in the first horizontal direction can independently be set, the repetition interval “f” of the gate electrode 122 in the second horizontal direction need to be matched with the repetition interval of the super junction structure and cannot independently be set. Therefore, as illustrated in FIG. 13, desirably the repetition interval “g” of the gate electrode 122 in the first horizontal direction is longer than the repetition interval “f” of the gate electrode 122 in the second horizontal direction. This facilitates the realization of the setting of b>d.

As described above, in the second embodiment, the gate electrode 122 is formed on the n pillar layers 112, p pillar layers 113, p base layers 114, and n⁺ source layers 116. Further, the n⁺ source layers 116 are formed into stripe shapes extending in the first horizontal direction without being formed into stripe shapes extending in the second horizontal direction. Accordingly, both the high-speed switching and the low noise level can be achieved while the low on-state resistance and the high avalanche capability are maintained. In the second embodiment, the offset mesh plane pattern is employed, and the n⁺ source layers 116 are not formed in the portions that do not constitute the current paths and in the corners of the p base layers 114.

### Third Embodiment

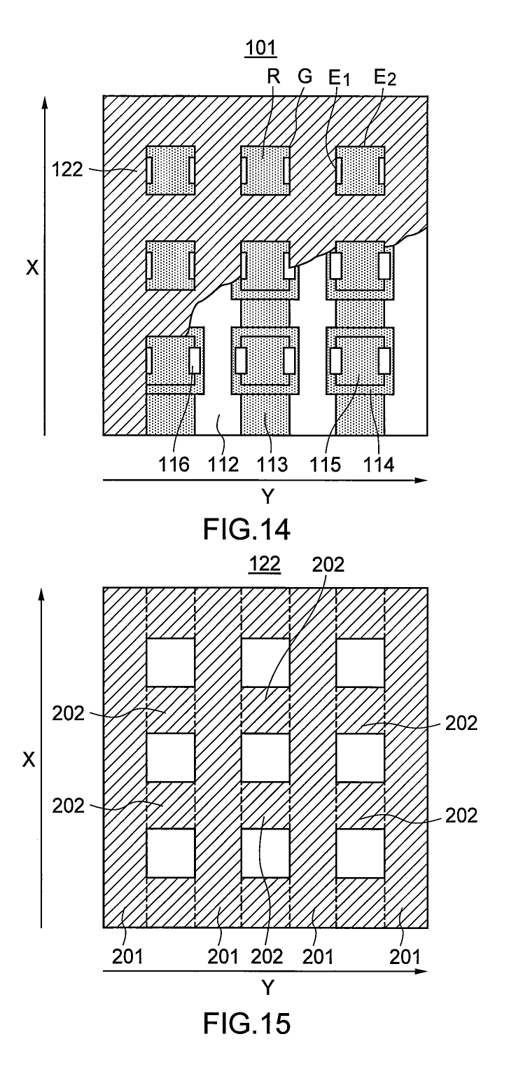

FIG. 14 shows a plan view schematically illustrating a configuration of a power semiconductor device 101 according to a third embodiment. As with the first and second embodiments, the power semiconductor device 101 of the third embodiment includes a vertical power MOSFET formed on the stripe-shaped super junction structure.

The gate electrodes 122 of the first embodiment have the ladder-like plane patterns as illustrated in FIG. 1(A), and the gate electrode 122 of the second embodiment has the offset mesh plane pattern as illustrated in FIG. 10(A). On the other hand, a gate electrode 122 of the third embodiment has a mesh plane pattern as illustrated in FIG. 14. The mesh plane pattern will be described in detail with reference to FIG. 15.

Referring to FIG. 15, the gate electrode 122 of the third embodiment includes plural stripe portions 201 and plural connection portions 202. The stripe portions 201 have stripe shapes extending in the first horizontal direction. The connection portions 202 connect the stripe portions 201 adjacent to each other. In the third embodiment, the mesh plane pattern is formed by the stripe portions 201 and connection portions 202 as illustrated in FIG. 15. The mesh plane pattern is formed in a periodical manner in the second horizontal direction by the stripe portions 201, and is also formed in a periodical manner in the first horizontal direction by the connection portions 202.

Referring back to FIG. 14, the description will be continued. However, the description regarding the stripe portions 201 and connection portions 202 will be described with reference to FIG. 15 as appropriate.

FIG. 14 shows, in addition to the plan view of the gate electrode 122, a plan view of each layer located under the gate electrode 122. As can be seen from FIGS. 14 and 15, the stripe portions 201 are mainly formed on the n pillar layers 112, p base layers 114, p⁺ contact layers 115, and n⁺ source layers 116, and the connection portions 202 are mainly formed on the p pillar layers 113.

As described above, the p base layers 114 and the p⁺ contact layers 115 are formed by using the gate electrode 122 as a mask. Therefore, the p base layers 114 and the p⁺ contact layers 115 are selectively formed in opening regions of the mesh gate electrode 122.

As described above, in the third embodiment, the gate electrode 122 is formed on the n pillar layers 112, p pillar layers 113, p base layers 114, and n⁺ source layers 116. As a result, the gate-drain capacitance is increased when the super junction structure is fully depleted, thereby realizing the high-speed switching and the low noise level.

As in FIG. 10(A), regions R, edges E₁, edges E₂, and corners G are illustrated in FIG. 14. In the third embodiment, as with the second embodiment, the p base layers 114 and the p⁺ contact layers 115 are formed into island shapes in the regions R, respectively. Further, as with the second embodiment, the n⁺ source layers 116 are formed in portions except for the underneath of the corners G, in portions under the edges E₁, so that the low on-state resistance and the high avalanche capability can be realized.

As described above, in the third embodiment, the gate electrode 122 is formed on the n pillar layers 112, p pillar layers 113, p base layers 114, and n⁺ source layers 116. Further, the n⁺ source layers 116 is formed into stripe shapes extending in the first horizontal direction without being formed into stripe shapes extending in the second horizontal direction. Accordingly, both the high-speed switching and the low noise level can be achieved while the low on-state resistance and the high avalanche capability are maintained. In the third embodiment, the mesh plane pattern is employed, and the n⁺ source layers 116 are not formed in portions that do not constitute the current paths and in the corners of the p base layers 114.

### Fourth Embodiment

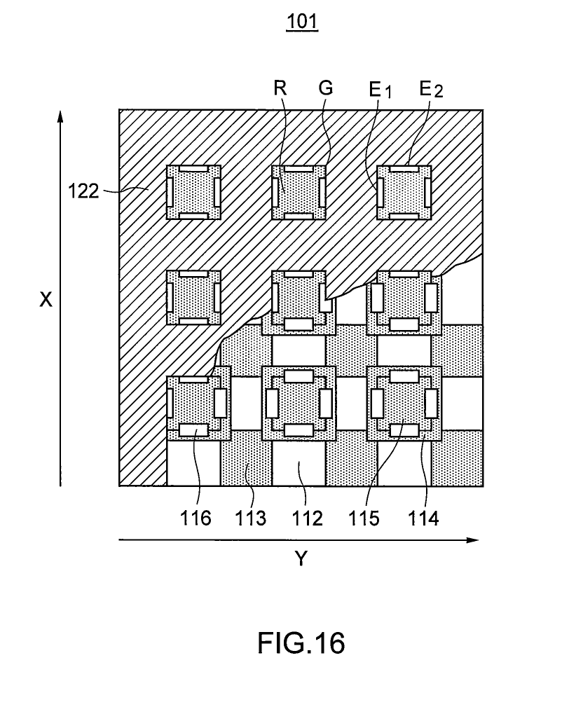

FIG. 16 shows a plan view schematically illustrating a configuration of a power semiconductor device 101 according to a fourth embodiment. The power semiconductor device 101 of the fourth embodiment includes a vertical power MOSFET formed on a lattice-shaped super junction structure, unlike the power semiconductor devices 101 of the first to third embodiments. The n pillar layers 112 and the p pillar layers 113 have square plane shapes, and are arranged in a lattice-shaped manner in the first and second horizontal directions. On the other hand, the gate electrode 122 has the mesh plane pattern as with the third embodiment. Therefore, as illustrated in FIG. 15, the gate electrode 122 of the fourth embodiment includes plural stripe portions 201 and plural connection portions 202. As illustrated in FIGS. 15 and 16, the stripe portions 201 are formed on the n pillar layers 112, the p pillar layers 113, the p base layers 114, and the n⁺ source layers 116, and the connection portions 202 are formed on the n pillar layers 112. In this embodiment, each stripe portion 201 is formed on n pillar layers 112, p pillar layers 113, p base layers 114, and n⁺ source layers 116 via the gate insulator, and each connection portion 202 is formed on an n pillar layer 112 via the gate insulator.

As in FIG. 14, regions R, edges E₁, edges E₂, and corners G are illustrated in FIG. 16. In the fourth embodiment, as with the third embodiment, the p base layers 114 and the p⁺ contact layers 115 are formed into island shapes in the regions R, respectively. Further, the p pillar layers 113 are formed so as to be located at the corners G of the p base layers 114, and the gate electrode 122 is formed on the p pillar layers 113. Therefore, when the super junction structure is fully depleted, the gate-drain capacitance is increased to realize the high-speed switching and the low noise level.

Further, in the fourth embodiment, the n⁺ source layers 116 are formed under the edges E₁ and E₂. Therefore, the n⁺ source layers 116 having stripe shapes extending in the second horizontal direction is formed, in addition to the n⁺ source layers 116 having stripe shapes extending in the first horizontal direction. In this way, the n⁺ source layers 116 are formed under the stripe portions 201 and the connection portions 202 in the fourth embodiment, unlike the first to third embodiments.

However, in the fourth embodiment, the n⁺ source layers 116 are formed in portions except for the underneath of the corners G, in portions under the edges E₁ and E₂, so that the low on-state resistance and the high avalanche capability can be realized like the first to third embodiments.

As described above, in the fourth embodiment, the gate electrode 122 is formed on the n pillar layers 112, p pillar layers 113, p base layers 114, and n⁺ source layers 116. Further, the n⁺ source layers 116 are formed into stripe shapes extending in the first horizontal direction and into stripe shapes extending in the second horizontal direction, but are not formed at the corners of the p base layers 114. Accordingly, both the high-speed switching and the low noise level can be achieved while the low on-state resistance and the high avalanche capability are maintained.

### Fifth Embodiment

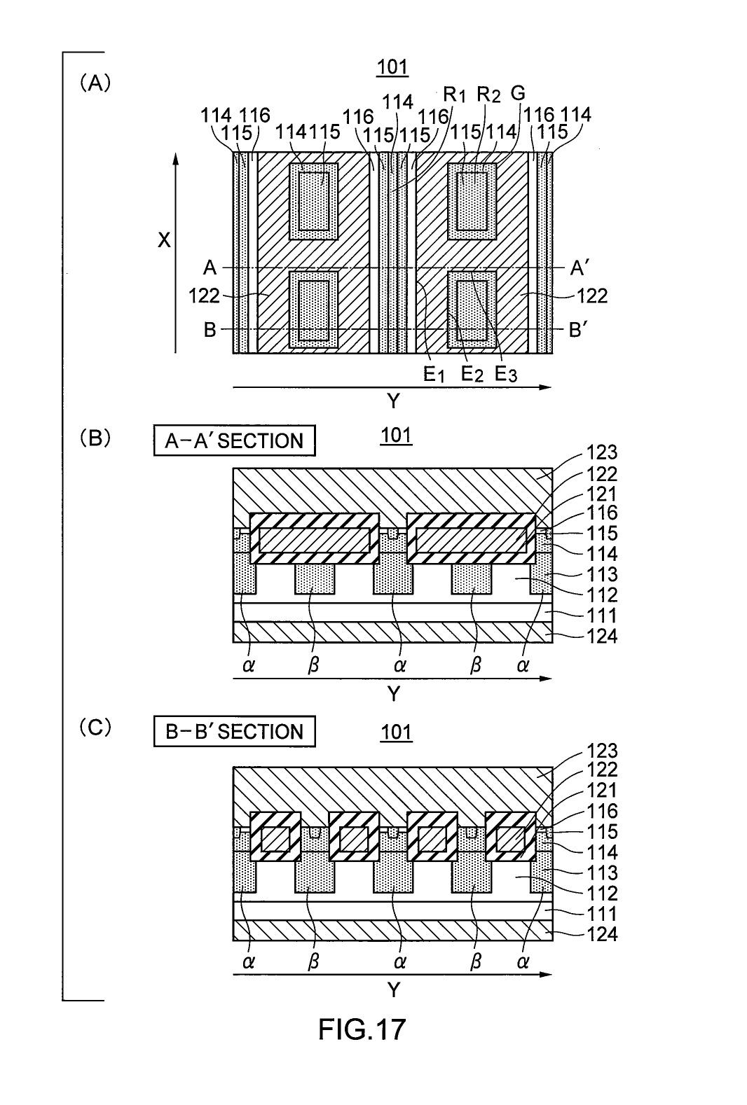

FIG. 17 shows a plan view and side sectional views schematically illustrating a configuration of a power semiconductor device according to a fifth embodiment. FIG. 17(A) is the plan view illustrating the power semiconductor device 101. FIG. 17(B) is the side sectional view taken along a line A-A′ in FIG. 17(A), and FIG. 17(C) is the side sectional view taken along a line B-B′ in FIG. 17(A). As illustrated in FIG. 17, the power semiconductor device 101 of the fifth embodiment includes a vertical power MOSFET.

While the MOSFETs of the first to fourth embodiments have the planar gate structure, MOSFETs of the fifth embodiment have a trench gate structure.

In the fifth embodiment, as with the first to fourth embodiments, the gate electrodes 122 are formed on the n pillar layers 112, p pillar layers 113, p base layers 114, and n⁺ source layers 116. Further, in the fifth embodiment, as with the first to third embodiments, the n⁺ source layers 116 are formed into stripe shapes extending in the first horizontal direction without being formed into stripe shapes extending in the second horizontal direction. Therefore, in the fifth embodiment, the loss and noise in switching can be reduced while the low on-state resistance and the high avalanche capability are maintained like the first to fourth embodiments.

The gate electrodes 122 of the fifth embodiment have ladder-like plane patterns. Alternatively, the gate electrodes 122 may have other patterns that are formed in a periodical manner in both the first horizontal direction and the second horizontal direction. For example, the gate electrode(s) 122 of the fifth embodiment may have an offset mesh plane pattern(s) or a mesh plane pattern(s).

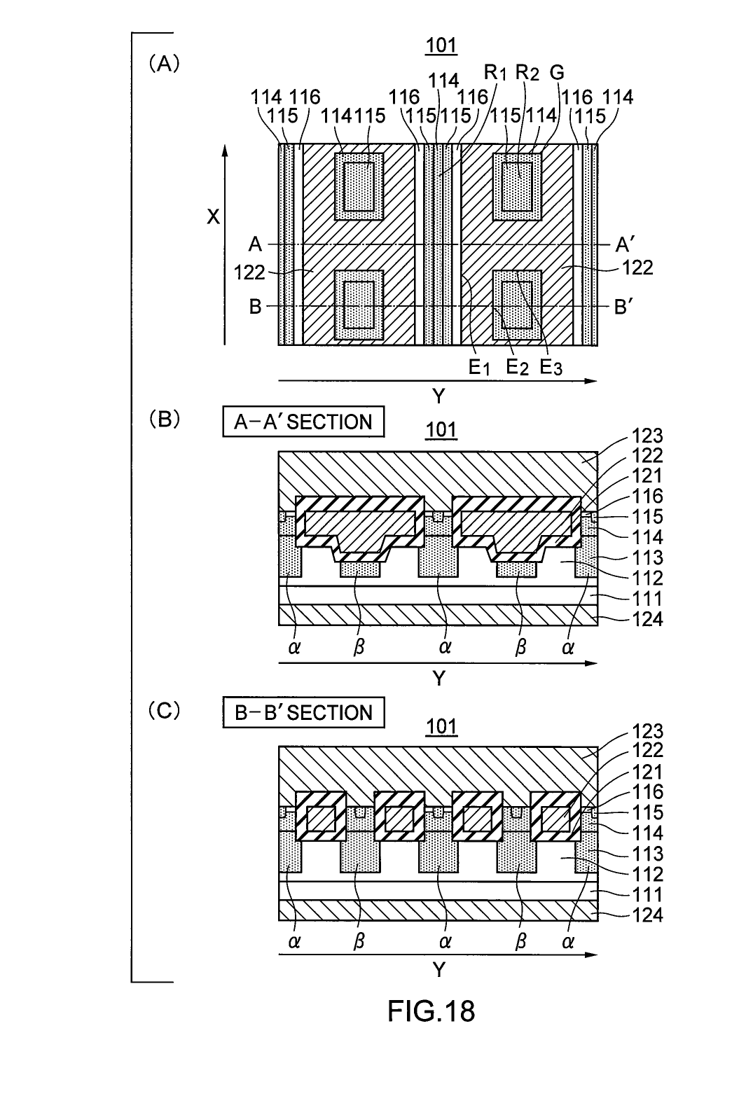

FIG. 18 illustrates a modification of the power semiconductor device 101 of the fifth embodiment. In the modification, a level of upper surfaces of the p pillar layers 113 located under the gate electrodes 122 are lower than a level of upper surfaces of the n pillar layers 112 and the other p pillar layers 113, as illustrated in FIGS. 18(B) and 18(C). As a result, the area in which the gate electrodes 122 are in contact with the p pillar layers 113 via the gate insulators 121. Such a structure has the effect of further increasing the gate-drain capacitance Cgd during high voltage application.

As described above, in the fifth embodiment, the gate electrodes 122 are formed on the n pillar layers 112, p pillar layers 113, p base layers 114, and n⁺ source layers 116. Further, the n⁺ source layers 116 are formed into stripe shapes extending in the first horizontal direction without being formed into stripe shapes extending in the second horizontal direction. Accordingly, both the high-speed switching and the low noise level can be achieved while the low on-state resistance and the high avalanche capability are maintained.

Although the first to fifth embodiments of the invention are described above by way of examples of specific aspects, the invention is not limited to these embodiments. For example, in the embodiments, the first conductivity type is set to an n-type, while the second conductivity type is set to a p-type. Alternatively, the first conductivity type may be set to a p-type, while the second conductivity type is set to an n-type. Those skilled in the art may appropriately select the shape, size, material and the like of each component in the embodiments from known techniques to obtain the operation and effect similar to those of the first to fifth embodiments. The obtained various modifications are also included in embodiments of the invention.

Further, any method of forming the super junction structure may be employed in the first to fifth embodiments. Examples of the method include a multi-epitaxial method in which ion implantation and buried epitaxial growth are repeated, a method of performing the ion implantation a plurality of times with different acceleration voltages, a method of re-burying a trench by crystal growth, a method of performing ion implantation from a direction oblique to a sidewall of the trench, and a method combining two or more of the methods.

The power semiconductor device 101 may include a transistor other than the vertical super junction MOSFET. Examples of the transistor include a lateral super junction MOSFET, a vertical super junction IGBT (Integrated Gate Bipolar Transistor), and a lateral super junction IGBT. Examples of a device provided in the power semiconductor device 101 include various super junction devices having MOS gates or MIS gates. In a case where an IGBT is used as the transistor instead of MOSFET, the source electrode 123 and the drain electrode 124 are respectively replaced by an emitter electrode and a collector electrode, and a p collector layer is provided as a component of the transistor.

As described above, according to the embodiments of the invention, in the power semiconductor device having the super junction structure, both the high-speed switching and the low noise level can be achieved while the low on-state resistance and the high avalanche capability are maintained.

1. A power semiconductor device comprising:
a first semiconductor layer of a first conductivity type;
second semiconductor layers of the first conductivity type and third semiconductor layers of a second conductivity type, which are formed on the first semiconductor layer, have stripe shapes extending in a first horizontal direction, and are alternately arranged along a second horizontal direction orthogonal to the first horizontal direction;
a fourth semiconductor layer of the second conductivity type, selectively formed on a surface of one of the third semiconductor layers;
a fifth semiconductor layer of the first conductivity type, selectively formed on a surface of the fourth semiconductor layer, and formed into a stripe shape extending in the first horizontal direction without being formed into a stripe shape extending in the second horizontal direction;
a control electrode formed on the second, third, fourth, and fifth semiconductor layers via an insulating layer, and having a plane pattern periodical in the first horizontal direction and the second horizontal direction;
a first main electrode electrically connected to the fourth and fifth semiconductor layers; and
a second main electrode electrically connected to the first semiconductor layer.

2. The device according to claim 1, wherein
the control electrode has the plane pattern including stripe portions which have stripe shapes extending in the first horizontal direction, and connection portions which connect the stripe portions to each other,
the stripe portions are formed on the second, fourth, and fifth semiconductor layers via the insulating layer,
the connection portions are formed on at least one of the third semiconductor layers via the insulating layer, and
the fifth semiconductor layer is not formed under the connection portions.

3. The device according to claim 2, wherein
the control electrode has a ladder-like plane pattern, and has a first edge which faces a region sandwiched between the control electrode and another control electrode, and a second edge which faces a region surrounded by the control electrode, and
the fifth semiconductor layer is formed under the first edge without being formed under the second edge.

4. The device according to claim 2, wherein
a repetition interval of the control electrode in the second horizontal direction is n times as large as a repetition interval of the third semiconductor layers in the second horizontal direction, where n is an integer of 2 or more.

5. The device according to claim 2, wherein
in the control electrode, a width of each of the connection portions in the first horizontal direction is larger than a distance between the connection portions adjacent to each other in the first horizontal direction.

6. The device according to claim 2, wherein
in the control electrode, a width of each of the stripe portions in the second horizontal direction is larger than a distance between the sprite portions adjacent to each other in the second horizontal direction.

7. The device according to claim 2, wherein
in the control electrode, a width of each of the connection portions in the first horizontal direction is larger than a width of each of the stripe portions in the second horizontal direction.

8. The device according to claim 2, wherein
a distance between the control electrode and another control electrode is larger than a distance between the sprite portions adjacent to each other in the second horizontal direction.

9. The device according to claim 2, wherein
an impurity concentration in the third semiconductor layers located under the connection portions is increased as a distance to the control electrode is shorter.

10. The device according to claim 2, wherein
a width of each of the connection portions in the first horizontal direction is one to four times as large as a depth of the fourth semiconductor layer.

11. The device according to claim 2, wherein
the control electrode has an offset mesh plane pattern, and has an edge of the stripe portions which faces a region surrounded by the control electrode, and an edge of the connection portions which faces the region surrounded by the control electrode, and
the fifth semiconductor layer is formed under the edge of the stripe portions without being formed under the edge of the connection portions.

12. The device according to claim 11, wherein
the fifth semiconductor layer is not formed under an intersection of the edge of the stripe portions and the edge of the connection portions.

13. The device according to claim 11, wherein
the edge of the stripe portions includes a first portion which faces the fifth semiconductor layer, and a second portion which does not face the fifth semiconductor layer, and
the first portion of the edge is longer than the second portion of the edge.

14. The device according to claim 11, wherein
each of the second semiconductor layers has a first side surface and a second side surface which face the third semiconductor layers, and is provided with first regions which are electrically connected to the fifth semiconductor layer at the first side surface, and second regions which are electrically connected to the fifth semiconductor layer at the second side surface, the first and second regions being alternately arranged along the first horizontal direction.

15. The device according to claim 11, wherein
a repetition interval of the control electrode in the first horizontal direction is longer than a repetition interval of the control electrode in the second horizontal direction.

16. The device according to claim 2, wherein
the control electrode has a mesh plane pattern, and has an edge of the stripe portions which faces a region surrounded by the control electrode, and an edge of the connection portions which faces the region surrounded by the control electrode, and
the fifth semiconductor layer is formed under the edge of the stripe portions without being formed under the edge of the connection portions.

17. The device according to claim 16, wherein
the fifth semiconductor layer is not formed under an intersection of the edge of the stripe portions and the edge of the connection portions.

18. A power semiconductor device comprising:
a first semiconductor layer of a first conductivity type;
second semiconductor layers of the first conductivity type and third semiconductor layers of a second conductivity type, which are formed on the first semiconductor layer, have square plane shapes, and are alternately arranged along a first horizontal direction and a second horizontal direction orthogonal to the first horizontal direction;
a fourth semiconductor layer of the second conductivity type, selectively formed on a surface of one of the third semiconductor layers;
fifth semiconductor layers of the first conductivity type, each of which is selectively formed on a surface of the fourth semiconductor layer, and is formed into a stripe shape extending in the first or second horizontal direction;
a control electrode formed on the second, third, fourth, and fifth semiconductor layers via an insulating layer, and having a plane pattern periodical in the first horizontal direction and the second horizontal direction;
a first main electrode electrically connected to the fourth and fifth semiconductor layers; and
a second main electrode electrically connected to the first semiconductor layer.

19. The device according to claim 18, wherein
the control electrode has the plane pattern including stripe portions which have stripe shapes extending in the first horizontal direction, and connection portions which connect the stripe portions to each other,
the stripe portions are formed on the second, third, fourth, and fifth semiconductor layers via the insulating layer,
the connection portions are formed on the second semiconductor layers via the insulating layer, and
the fifth semiconductor layers are formed under the stripe portions and the connection portions.

20. The device according to claim 1, wherein
the control electrode, the first main electrode, and the second main electrode are respectively a gate electrode, a source electrode, and a drain electrode which form a planar gate structure or a trench gate structure.
